(19) United States
(12) Patent Application Publication
(10) Pub. No.: US 2026/0107457 A1
(43) Pub. Date: Apr. 16, 2026

(54) SELF-ALIGNED METHOD OF FORMING EEPROM CELLS

(71) Applicant: Silicon Storage Technology, Inc., San Jose, CA (US)

(72) Inventors: JENG-WEI YANG, Zhubei City (TW); MAN-TANG WU, Hsinchu (TW); GINA CHOU, New Taipei City (TW); NATHAN CHEN, Hsinchu (TW); XIAN LIU, Sunnyvale, CA (US); NHAN DO, Saratoga, CA (US)

(21) Appl. No.: 19/046,451

(22) Filed: Feb. 5, 2025

Related U.S. Application Data
(60) Provisional application No. 63/707,043, filed on Oct. 14, 2024.

(51) Int. Cl. H10B 41/27; H10D 30/01; H10D 30/68

(52) U.S. Cl. CPC H10B 41/27; H10D 30/0411; H10D 30/6892

(57) ABSTRACT

An EEPROM cell with junction, source and drain regions in a semiconductor substrate. A memory channel region extends between the source and junction regions. A select channel region extends between the drain and junction regions. A floating gate has a first portion disposed over the junction region and insulated therefrom by a first insulation layer, and a second portion disposed over the memory channel region and insulated therefrom by a second insulation layer. A sense gate is disposed over the floating gate. The sense gate wraps around an edge of the first portion without wrapping around an edge of the second portion. A select gate is disposed over the select channel region. The select gate is insulated from the select channel region by a third insulation layer. The third insulation layer is thinner than the second insulation layer and thicker than the first insulation layer.

This application claims the benefit of U.S. Provisional Application No. 63/707,043, filed Oct. 14, 2024, and which is incorporated herein by reference.

### FIELD OF THE INVENTION

The present invention relates to EEPROMs (Electrically Erasable Programmable Read-Only Memory).

### BACKGROUND OF THE INVENTION

EEPROM is a type of non-volatile ROM that enables individual bytes of data to be erased from, and reprogrammed to, individual memory cells. FIG. 1 illustrates a conventional example of an EEPROM cell. The memory cell 1 is formed on a semiconductor substrate 2 (e.g., silicon), in which a source region 3, a drain region 4 and a junction region 5 are formed in the semiconductor substrate 2, where these regions have a conductivity type (e.g. N or N+ type) different from that of the surrounding portion of the semiconductor substrate 2 (e.g., P type). A memory channel region 6 of semiconductor substrate 2 extends between the source region 3 and the junction region 5, and a select channel region 7 of the semiconductor substrate 2 extends between the junction region 5 and drain region 4. A floating gate 8 of conductive material is disposed over and insulated from the memory channel region 6, for controlling the conductivity of the memory channel region 6. A sense gate 9 of conductive material is disposed above and to the side of (and insulated from) the floating gate 8. A select gate 10 of conductive material is disposed over and insulated from the select channel region 7, for controlling the conductivity of the select channel region 7. Data can be stored in, and removed from, the memory cell 1 by changing the program state of the floating gate 8 (i.e., changing the number of electrons on the floating gate 8), which in turn affects the conductivity of the underlying memory channel region 6 when appropriate read operation voltages are applied to the memory cell 1. The select gate 10 is used to select the memory cell 1 for program, erase and read operations by turning on the select channel region 7 (i.e., make the select channel region 7 conductive by placing a positive voltage on the select gate 10).

FIG. 2 illustrates another conventional example of an EEPROM cell, which is the same as that in FIG. 1 except that the sense gate 9 is disposed over the floating gate 8, but not also along the sides of the floating gate 8. This example can include a dummy gate 11 over the select gate 10. The advantage of this example is that the memory cell can be made laterally smaller. However, there is a need for a method of reliably making the EEPROM cell even smaller in the lateral direction.

### BRIEF SUMMARY OF THE INVENTION

The aforementioned problems and needs are addressed by a method of forming an EEPROM cell that comprises:
forming a first insulation layer on a portion of an upper surface of a semiconductor substrate;
forming a second insulation layer on the first insulation layer;
forming a trench extending through the first and second insulation layers;
forming an insulation spacer along a sidewall of the trench;
forming a junction region in the semiconductor substrate under the trench;
forming an insulation block in the trench, wherein the insulation spacer is disposed between the insulation block and the first insulation layer;

removing the second insulation layer and the insulation spacer;
forming a third insulation layer on the upper surface of the semiconductor substrate between the insulation block and the first insulation layer;
forming a first conductive block on the first insulation layer and on the third insulation layer;
forming a fourth insulation layer on the first conductive block and on the insulation block;
forming a fifth insulation layer on a portion of the upper surface of the semiconductor substrate;
forming a second conductive block on the fourth insulation layer;
forming a third conductive block on the fifth insulation layer;
forming a source region in the semiconductor substrate, wherein a memory channel region of the semiconductor substrate extends between the source region and the junction region; and
forming a drain region in the semiconductor substrate, wherein a select channel region extends between the drain region and the junction region;
wherein:
   the first conductive block has a first portion disposed over the junction region and insulated from the junction region by the third insulation layer, and a second portion disposed over the memory channel region and insulated from the memory channel region by the first insulation layer,
   the second conductive block wraps around an edge of the first portion of the first conductive block without wrapping around an edge of the second portion of the first conductive block, and
   the third conductive block is disposed over the select channel region and insulated from the select channel region by the fifth insulation layer.

An EEPROM cell, comprises a semiconductor substrate; a junction region formed in the semiconductor substrate; a source region formed in the semiconductor substrate, with a memory channel region of the semiconductor substrate extending between the source region and the junction region; a drain region formed in the semiconductor substrate, with a select channel region of the semiconductor substrate extending between the drain region and the junction region; a floating gate having a first portion disposed over the junction region and a second portion disposed over the memory channel region, wherein the first portion is insulated from the junction region by a first insulation layer, and wherein the second portion is insulated from the memory channel region by a second insulation layer; a sense gate that is disposed over the floating gate, wherein the sense gate wraps around an edge of the first portion of the floating gate without wrapping around an edge of the second portion of the floating gate; and a select gate disposed over the select channel region, wherein the select gate is insulated from the select channel region by a third insulation layer; wherein the third insulation layer has a thickness that is less than the thickness of the second insulation layer and greater than the thickness of the first insulation layer.

Other objects and features of the present disclosure will become apparent by a review of the specification, claims and appended figures.

### BRIEF DESCRIPTION OF THE DRAWINGS

FIG. 1 is a cross sectional view of a conventional EEPROM cell.

FIG. 2 is a cross sectional view of a conventional EEPROM cell.

FIGS. 3A-3W are side cross sectional views illustrating the formation of an EEPROM cell.

FIG. 4 is a side cross sectional view illustrating a pair of the EEPROM cells.

FIG. 5 is a side cross sectional view illustrating the EEPROM cell.

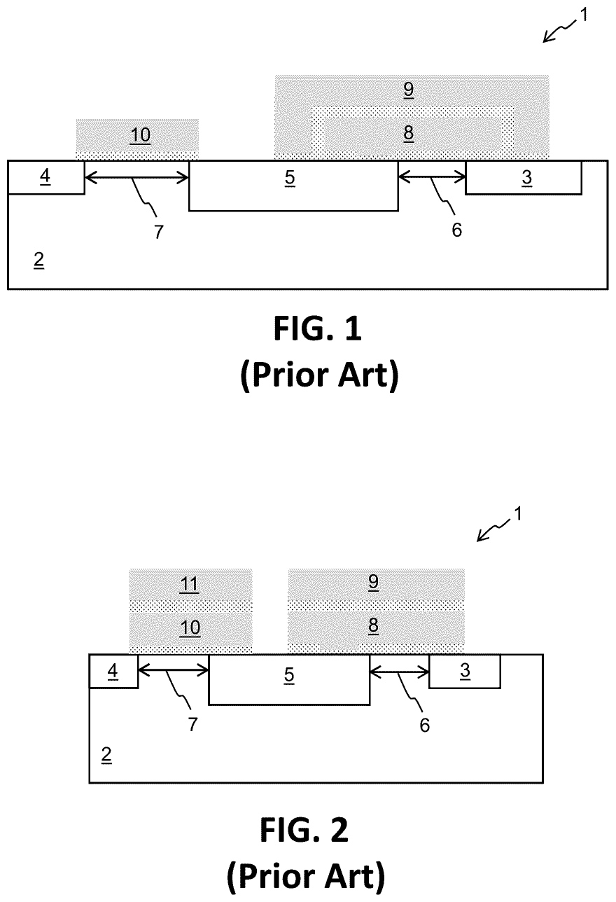

### DETAILED DESCRIPTION OF THE INVENTION

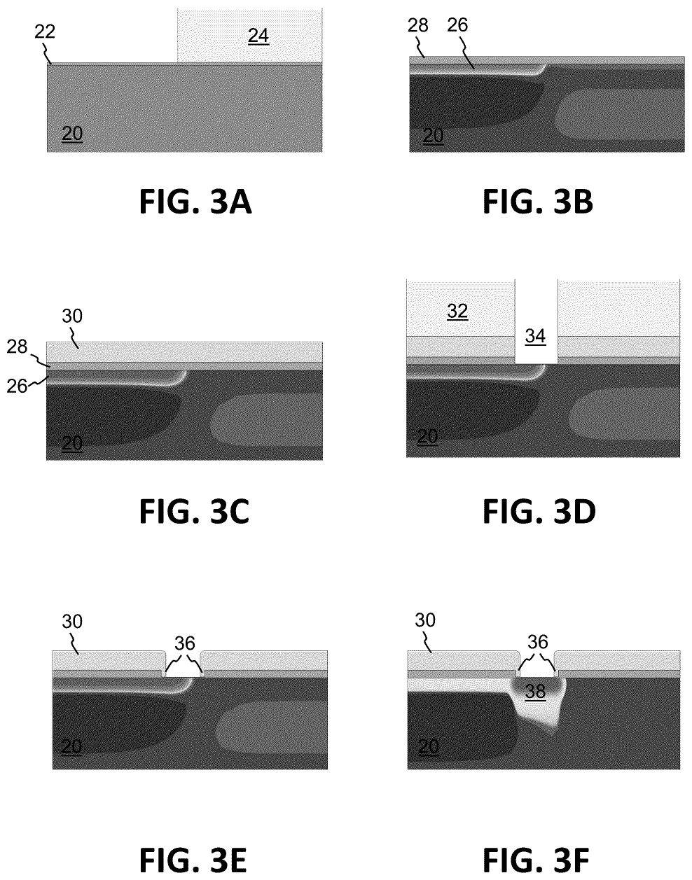

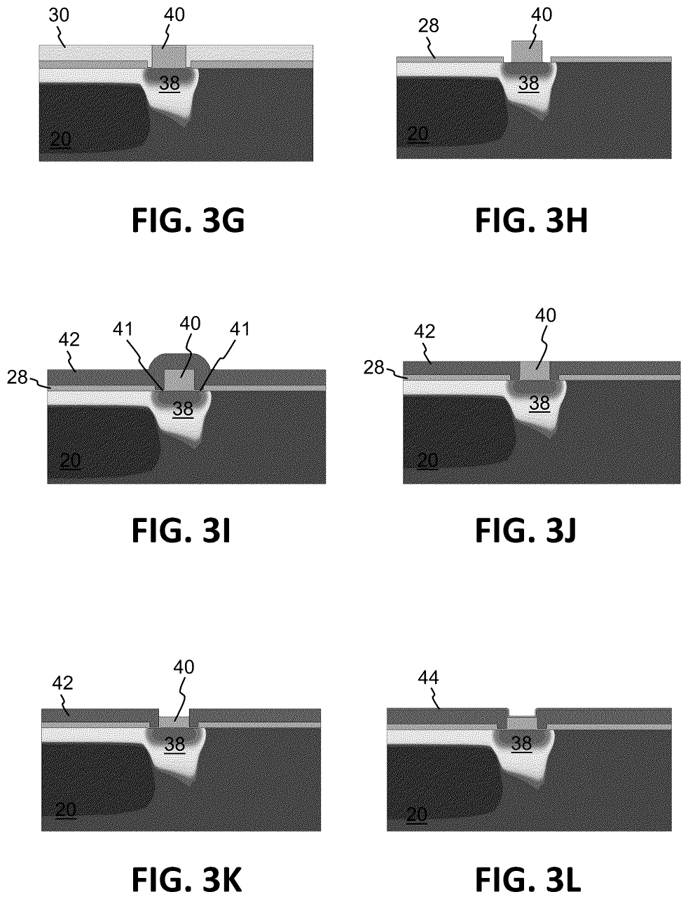

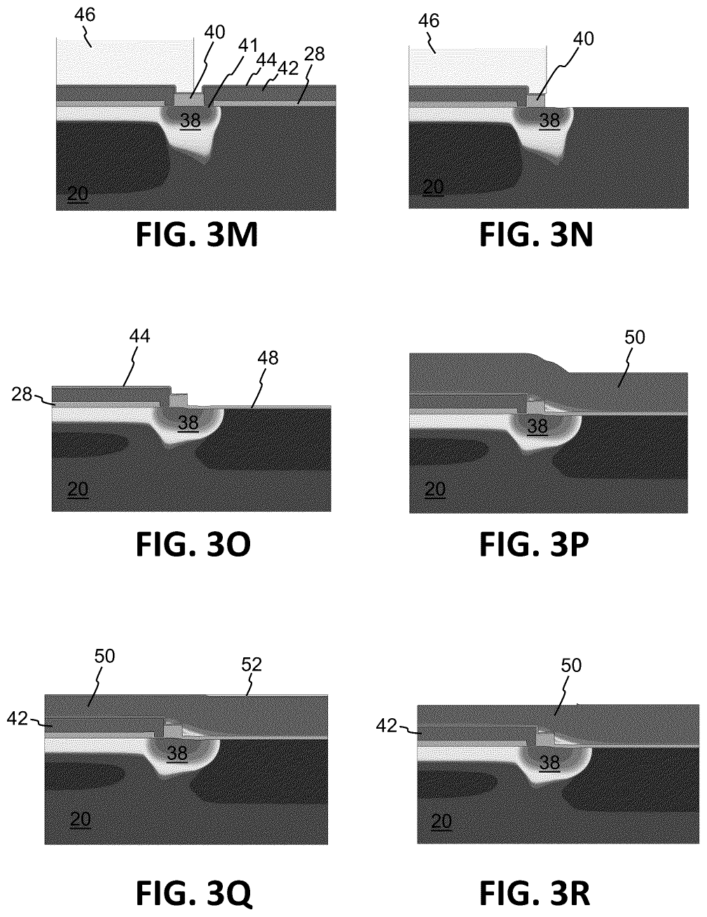

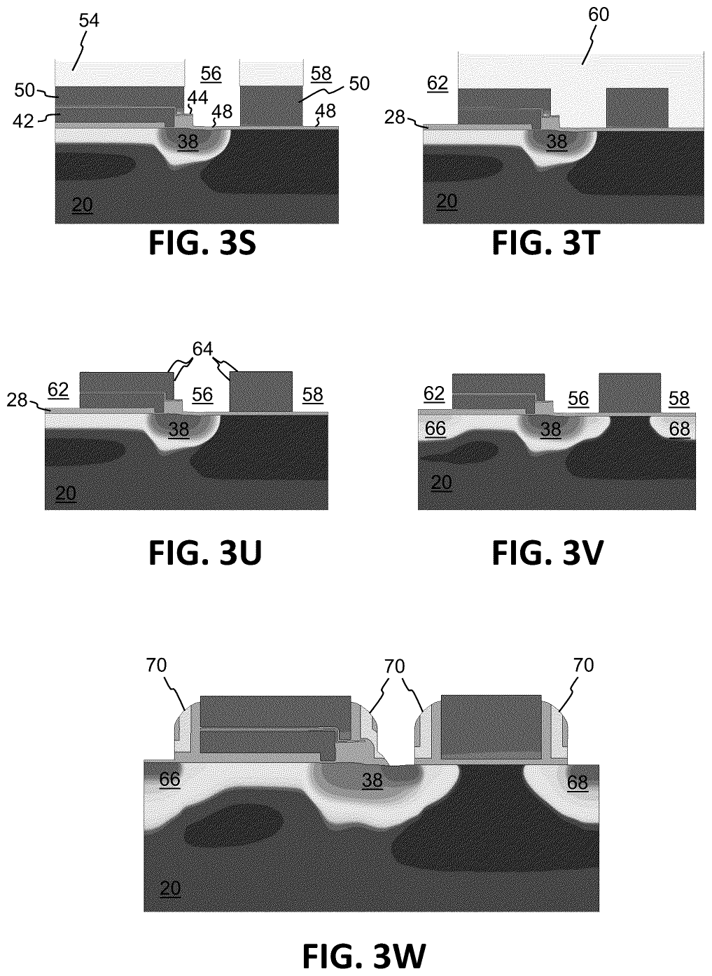

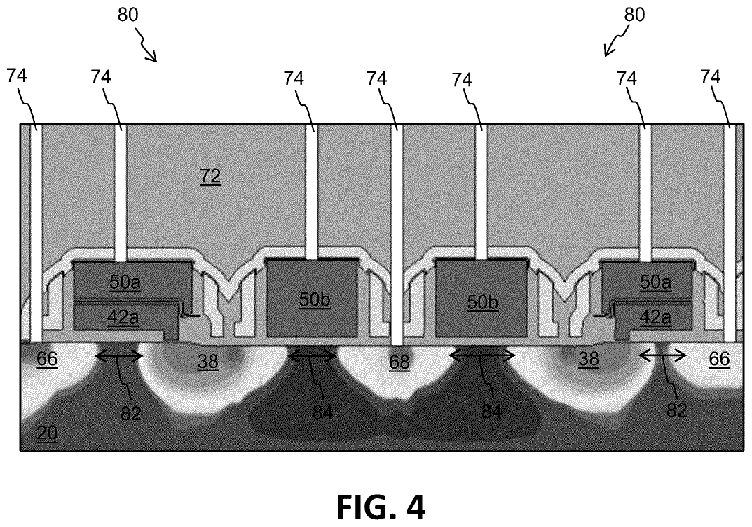

The present example is a method of forming a semiconductor device with EEPROM cells (memory cells). The method is illustrated in FIGS. 3A-3W, and begins with forming an insulation layer 22 (e.g., silicon oxide, silicon dioxide, or a combination of both, collectively referred to herein as oxide) on an upper surface of a semiconductor substrate 20 (e.g., silicon). Photoresist 24 is formed on insulation layer 22 and patterned (i.e., selectively exposed, developed and partially removed) leaving portions of insulation layer 22 covered and others exposed, as illustrated in FIG. 3A. An implantation is performed to create an implanted region 26 in the semiconductor substrate 20 (which eventually will be the memory channel region). After the photoresist 24 and insulation layer 22 are removed, insulation layer 28 (e.g., oxide) is formed on the upper surface of the semiconductor substrate 20, as shown in FIG. 3B.

An insulation layer 30 (e.g., silicon nitride, also referred to herein as nitride) is formed on insulation layer 28 (FIG. 3C). Photoresist 32 is formed over the structure, and patterned (i.e., exposed, developed and partially removed) to form a trench 34. One or more etches are used to extend the trench 34 down through insulation layer 30 and insulation layer 28, to expose semiconductor substrate 20 (FIG. 3D). After photoresist 32 is removed, spacers of insulation material are formed in the trench 34. Spacer formation is well known, and includes material deposition and anisotropic etch, which removes the material from horizontal surfaces but leaves spacers of the material along vertical surfaces. In this case, insulation material deposition (e.g., nitride) and etch leaves insulation spacers 36 along the sidewalls of trench 34 (FIG. 3E). An implantation is used to form a junction region 38 in the semiconductor substrate 20 under the trench 34 (FIG. 3F). Insulation material deposition and CMP (chemical mechanical polish) are used to fill trench 34 with an insulation block 40 (e.g., of oxide), as shown in FIG. 3G. An etch is used to remove the insulation layer 30 and spacers 36 (FIG. 3H).

An insulation layer 41 is formed on the structure. Insulation layer 41 can be oxide, where insulation layer 41 is formed on the exposed upper surface of the semiconductor substrate 20 on either side of insulation block 40 (i.e., in the locations from which spacers 36 were previously removed), and can serve to thicken insulation block 40 and insulation layer 28. A first conductive layer 42 (e.g., polysilicon, also referred to herein as poly) is then formed over the structure, as shown in FIG. 3I. The structure is planarized using CMP, using the insulation block 40 as a stop, so that conductive layer 42 is removed from the upper surface of insulation block 40 (FIG. 3J). An etch is used to recess the upper surface of insulation block 40 below the upper surface of conductive layer 42 (FIG. 3K). An insulation layer 44 is formed over the structure (e.g., an ONO layer with oxide-nitride-oxide sublayers, with a nitride sublayer disposed between a pair of oxide sublayers) (FIG. 3L). Photoresist 46 is formed and patterned to expose a portion of insulation layer 44 over insulation block 40 and a portion of insulation layer 44 to one side of the insulation block 40 (FIG. 3M). One or more etches are used to remove portions of insulation layer 44, conductive layer 42, and insulation layers 41 and 28 which are not disposed under (and protected by) photoresist 46 (FIG. 3N). A portion of insulation block 40 is also removed.

After photoresist 46 is removed, an insulation layer 48 (e.g., oxide) is formed on the structure, which can serve to thicken the remaining portion of insulation layer 44 (FIG. 3O). A second conductive layer 50 (e.g., poly) is formed on the structure (FIG. 3P). An insulation layer 52 (e.g., oxide) is formed on the structure, followed by CMP using the insulation layer 52 on the lower portion of conductive layer 50 as a stop (FIG. 3Q). An etch is used to remove the remaining portion of insulation layer 52 (FIG. 3R). Photoresist 54 is formed on the structure, and patterned to form a first trench 56 and second trench 58 exposing portions of the underlying conductive layer 50. One or more etches are used to extend the first trench 56 down to and expose a portion of insulation layer 44 (that is on insulation block 40) and a portion of insulation layer 48 (that is over junction region 38), and extend the second trench 58 down to and expose another portion of insulation layer 48, as shown in FIG. 3S. A block 50b of conductive layer 50 remains between first and second trenches 56 and 58.

After photoresist 54 is removed, photoresist 60 is formed on the structure, and patterned to form a third trench 62. One or more etches are used extend the third trench 62 through conductive layer 50, insulation layer 44, and conductive layer 42, to expose a portion of insulation layer 28, and leave a block 50a of conductive layer 50 and a block 42a of conductive layer 42 between trenches 56, 62 (FIG. 3T). After photoresist 60 is removed, a thermal oxidation is used to form an oxide layer 64 on the exposed surfaces of conductive layers 42 and 50 (FIG. 3U). An implantation is used to form source region 66 and drain region 68 in the semiconductor substrate 20 under third and second trenches 62, 58 respectively (FIG. 3V). This implantation can enhance junction region 38 under first trench 56. Composite insulation spacers 70 (e.g., combination of oxide and nitride) are formed on the sidewalls of trenches 56, 58, 62. One or more additional implantations can be performed to enhance the source region 66 and drain region 68 and junction region 38. The resulting structure is shown in FIG. 3W.

The structure is covered by insulation material 72, with contact holes formed through the insulation material 72 that are filled with conductive material (e.g., metal) to form electrical contacts 74 that electrically connect with various components. The final structure is shown in FIG. 4, which illustrates a pair of memory cells 80 sharing a common drain region 68. Each memory cell 80 includes a source region 66, a junction region 38, a drain region 68. A memory channel region 82 of the semiconductor substrate 20 extends between the source region 66 and junction region 38. A select channel region 84 of the semiconductor substrate 20 extends between the junction region 38 and drain region 68. A floating gate 42a (which is a remaining block of conductive layer 42, i.e., a first conductive block) is disposed over and insulated from (for controlling the conductivity of) memory channel region 82. A sense gate 50a (which is a remaining block of conductive layer 50, i.e., a second conductive block) is disposed over and insulated from the floating gate 42a. A select gate 50b (which is another remaining block of conductive layer 50, i.e., a third conductive block) is disposed over and insulated from (for controlling the conductivity of) select channel region 84. The various electrical contacts 74 can electrically connect with source regions 66, drain regions 68, sense gates 50a, and select gates 50b. The memory cells 80 are formed in pairs sharing a common drain region 68, with two adjacent pairs of the memory cells sharing a common source region 66.

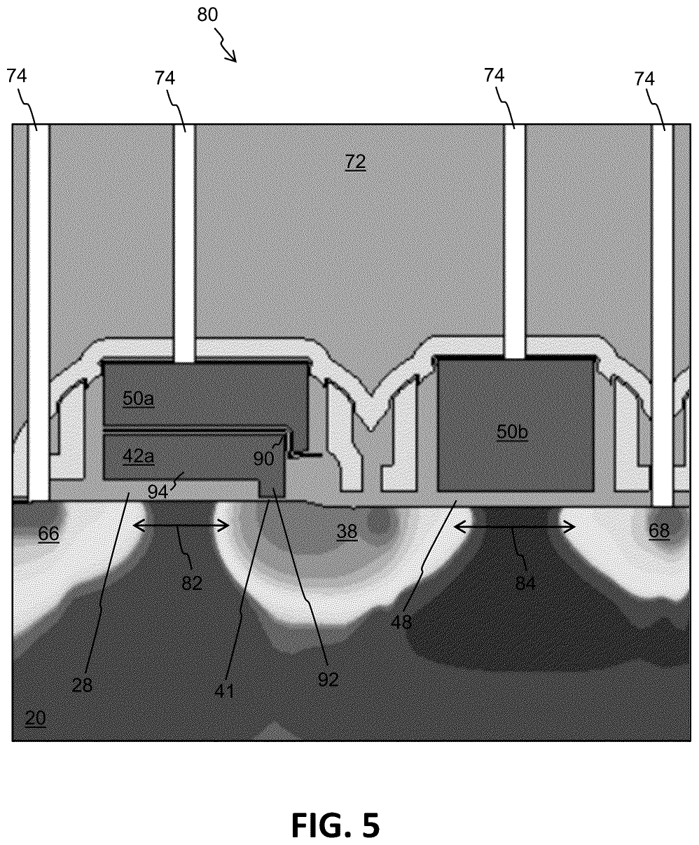

As best shown in FIG. 5, the floating gate 42a includes a first portion 92 that is disposed over junction region 38 and is insulated therefrom by insulation layer 41, and a second portion 94 that disposed over memory channel region 82 and is insulated therefrom by insulation layer 28. The sense gate 50a wraps around an edge 90 of the first portion 92 of floating gate 42a (i.e., the sense gate 50a extends along a top surface and a side surface of first portion 92 of floating gate 42a), for better capacitive coupling between the sense gate 50a and floating gate 42a. The sense gate 50a does not wrap around an edge of the second portion 94 of floating gate 42a (i.e., the side surfaces of sense gate 50a and second portion 94 of floating gate 42a are aligned to each other, because a common etch defines both). Insulation layer 41 has a thickness that is less than a thickness of insulation layer 28, to enhance electron tunneling during program and erase operations between floating gate 42a and junction region 38. Having insulation layer 28 be thicker than insulation layer 41 provides for better performance by the floating gate 42a in controlling the conductivity of memory channel region 82 without excessive capacitive coupling between the second portion 94 of floating gate 42a and semiconductor substrate 20.

The select gate 50b over select channel region 84 forms a select transistor for selecting the memory cell 80 during program, read and erase operations. To program the memory cell 80 (i.e., remove electrons from the floating gate 42a), positive voltages are applied to the source region 66, drain region 68 and select gate 50b, and a negative voltage is applied to sense gate 50a. The positive voltage on select gate 50b turns on select channel region 84 (i.e., makes select channel region 84 conductive) so that the positive voltage on drain region 68 is applied to junction region 38 via the select channel region 84. The negative voltage on the sense gate 50a is capacitively coupled to the floating gate 42a which (in combination with the positive voltage on the junction region 38) causes electrons on the floating gate 42a to tunnel from the first portion 92 of floating gate 42a, through insulation layer 41, to the junction region 38 (thereby removing electrons from the floating gate 42a). A non-limiting example of voltages for a program operation can include 5 V for the source region, 8.5 V for the drain region 68, 10.5 V for the select gate 50b, and −8.5 V for the sense gate 50a.

To erase the memory cell 80 (i.e., add electrons to the floating gate 42a), a zero or ground voltage is applied to the source region 66 and drain region 68, and positive voltages are applied to the sense gate 50a and the select gate 50b. The positive voltage on select gate 50b turns on select channel region 84 so that the zero or ground voltage on drain region 68 is applied to junction region 38 via the select channel region 84. The positive voltage on the sense gate 50a is capacitively coupled to the floating gate 42a which (in combination with the zero or ground voltage on the junction region 38) which causes electrons to tunnel from the junction region 38, through the insulation layer 41, to the floating gate 42a (thereby adding electrons to the floating gate 42a). A non-limiting example of voltages for an erase operation can include 0 V for the source region, 0 V for the drain region 68, 10.5 V for the select gate 50b, and 13.5 V for the sense gate 50a.

To read the memory cell 80 (i.e., determine is program state), positive voltages are applied to the select gate 50b, sense gate 50a and one of the source region 66 or drain region 68, whereby read current flowing between the source region 66 and drain region 68 will vary depending upon the number of electrons on the floating gate 42a. The number of electrons on the floating gate 42a therefore represent the program state of the memory cell 80, and therefore can represent a bit of data stored in the memory cell. The read current between source region 66 and drain region 68 is sensed in the read operation, where a relatively high number of electrons on the floating gate 42a will result in a relatively low read current, and a relatively low number of electrons on the floating gate 42a will result in a relatively high read current.

The above described formation method allows for better scaling down of the size of the memory cell 80. The junction region 38 is self-aligned to the floating gate 42a and sense gate 50a on one side, and the select gate 50b on the other side, making small dimensions reliably possible. Using spacers 36 to define the small length of floating gate first portion 92 results in a lower cell size and reduced capacitive coupling between the floating gate 42a and junction region 38 for better program and erase efficiencies. Having the sense gate 50a wrap around an edge of the first portion 92 of the floating gate 42a but not wrap around an edge of the second portion 94 of the floating gate 42a balances capacitive coupling efficiency with small lateral memory cell dimensions. Forming the insulation layer 48 (between the select gate 50b and select channel region 84) separately from insulation layers 41 and 28 allows for independently optimizing the thickness of insulation layer 48 and therefore the performance of select gate 50b. As a non-limiting example, the thickness of insulation layer 48 can be less than the thickness of insulation layer 28 and greater than the thickness of insulation layer 41. The scaling options also mean that lower operational voltages may be used to program, erase or read the memory cell 80.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper formation of the EEPROM cell described herein. Single layers of material could be formed as multiple layers of such or similar materials, and vice versa. The terms “forming” and “formed” as used herein shall include material deposition, material growth, or any other technique in providing the material as disclosed or claimed. Finally, the claims are comprising claims unless otherwise stated, and therefore “each” of a plurality of elements having a limitation does not preclude the inclusion of additional such elements lacking the limitation unless otherwise specifically claimed.

What is claimed is:

1. A method of forming an EEPROM cell, comprising:
forming a first insulation layer on a portion of an upper surface of a semiconductor substrate;
forming a second insulation layer on the first insulation layer;
forming a trench extending through the first and second insulation layers;
forming an insulation spacer along a sidewall of the trench;
forming a junction region in the semiconductor substrate under the trench;
forming an insulation block in the trench, wherein the insulation spacer is disposed between the insulation block and the first insulation layer;
removing the second insulation layer and the insulation spacer;
forming a third insulation layer on the upper surface of the semiconductor substrate between the insulation block and the first insulation layer;
forming a first conductive block on the first insulation layer and on the third insulation layer;
forming a fourth insulation layer on the first conductive block and on the insulation block;
forming a fifth insulation layer on a portion of the upper surface of the semiconductor substrate;
forming a second conductive block on the fourth insulation layer;
forming a third conductive block on the fifth insulation layer;
forming a source region in the semiconductor substrate, wherein a memory channel region of the semiconductor substrate extends between the source region and the junction region; and
forming a drain region in the semiconductor substrate, wherein a select channel region extends between the drain region and the junction region;
wherein:
the first conductive block has a first portion disposed over the junction region and insulated from the junction region by the third insulation layer, and a second portion disposed over the memory channel region and insulated from the memory channel region by the first insulation layer,
the second conductive block wraps around an edge of the first portion of the first conductive block without wrapping around an edge of the second portion of the first conductive block, and
the third conductive block is disposed over the select channel region and insulated from the select channel region by the fifth insulation layer.

2. The method of claim 1, wherein the first insulation layer has a thickness that is greater than a thickness of the third insulation layer.

3. The method of claim 1, wherein the fifth insulation layer has a thickness that is less than a thickness of the first insulation layer and greater than a thickness of the third insulation layer.

4. The method of claim 1, wherein the fourth insulation layer comprises a nitride sublayer between a pair of oxide sublayers.

5. The method of claim 1, wherein the forming of the first conductive block comprises:
forming a first conductive layer on the first insulation layer, on the third insulation layer and on the insulation block; and
performing a chemical mechanical polish to planarize an upper surface of the first conductive layer and to remove the first conductive layer from the insulation block.

6. The method of claim 5, wherein the forming of the first conductive block, the second conductive block and the third conductive block comprises:
forming a second conductive layer on the fourth insulation layer and on the fifth insulation layer;
performing a chemical mechanical polish to planarize an upper surface of the second conductive layer;
forming a first trench and a second trench that each extends through the second conductive layer and exposes the fifth insulation layer, wherein the third conductive block is disposed between the first and second trenches; and
forming a third trench that extends through the second conductive layer, the fourth insulation layer and the first conductive layer and exposes the first insulation layer, wherein the first and second conductive blocks are disposed between the first and third trenches.

7. The method of claim 6, wherein the junction region is disposed under the first trench, the drain region is disposed under the second trench, and the source region is disposed under the third trench.

8. An EEPROM cell, comprising:
a semiconductor substrate;
a junction region formed in the semiconductor substrate;
a source region formed in the semiconductor substrate, with a memory channel region of the semiconductor substrate extending between the source region and the junction region;
a drain region formed in the semiconductor substrate, with a select channel region of the semiconductor substrate extending between the drain region and the junction region;
a floating gate having a first portion disposed over the junction region and a second portion disposed over the memory channel region, wherein the first portion is insulated from the junction region by a first insulation layer, and wherein the second portion is insulated from the memory channel region by a second insulation layer;
a sense gate that is disposed over the floating gate, wherein the sense gate wraps around an edge of the first portion of the floating gate without wrapping around an edge of the second portion of the floating gate; and
a select gate disposed over the select channel region, wherein the select gate is insulated from the select channel region by a third insulation layer;
wherein the third insulation layer has a thickness that is less than the thickness of the second insulation layer and greater than the thickness of the first insulation layer.

9. The EEPROM cell of claim 8, wherein the sense gate is insulated from the floating gate by an insulation layer that comprises a nitride sublayer between a pair of oxide sublayers.
